(19) United States
(12) Patent Application Publication
(10) Pub. No.: US 2026/0352167 A1
(43) Pub. Date: Nov. 5, 2026

(54) CURRENT BASED DEVICE FILTER

(71) Applicant: TEXAS INSTRUMENTS INCORPORATED, Dallas, TX (US)

(72) Inventors: Radhika Juluri, Bangalore (IN); Manish Mukherjee, Bangalore (IN); Prakhar Agrawal, Bangalore (IN); Srinivas Veeramreddi, Bengaluru (IN); Aadithyaa M, Bangalore (IN)

(21) Appl. No.: 19/194,612

(22) Filed: Apr. 30, 2025

(51) Int. Cl. H03F 3/19; H03H 11/34

(52) U.S. Cl. CPC H03F 3/19; H03H 11/344

(57) ABSTRACT

A circuit comprising a first input stage with an input that receives an input current and an output; a first amplifier with an input coupled to the output of the first input stage and an output; a second amplifier with an input coupled to the output of the first amplifier and an output; a first resistor coupled between the output of the first amplifier and the input of the second amplifier; a first capacitor coupled to the first resistor and to the input of the second amplifier; a first output stage with an input coupled to the output of the second amplifier and an output configured to provide an output current; and a first feedback path coupled between the second amplifier and the input of the first amplifier, which includes a buffer with its output coupled to the input of the first amplifier and a second capacitor.

### BACKGROUND

Device filters are used to attenuate certain frequency components of an input signal. A device filter can be implemented as a low-pass filter, a high-pass filter, or a band-pass filter. An example of a low-pass filter is a basic RC circuit having a resistor (R) and capacitor (C) in series. The capacitor attenuates (or blocks) high frequency components of the input signal while allowing low-frequency components of the input signal to pass. Thus, for example in some audio applications, a low-pass filter can receive an input signal with a mix of soothing, low-frequency components and unwanted high-frequency (“screech”) components, and can attenuate the unwanted high-frequency components while allowing low-frequency components to provide an output signal that is more soothing to the human ear.

### SUMMARY

In accordance to an embodiment, a circuit includes: a first input stage having an input configured to receive an input current, and an output; a first amplifier having an input coupled to the output of the first input stage, and an output; a second amplifier having an input coupled to the output of the first amplifier, and an output; a first resistor coupled between the output of the first amplifier and the input of the second amplifier; a first capacitor coupled to the first resistor and to the input of the second amplifier; a first output stage having an input coupled to the output of the second amplifier, and an output configured to provide an output current; and a first feedback path coupled between the second amplifier and the input of the first amplifier. The first feedback path includes: a buffer having an output coupled to the input of the first amplifier, and a second capacitor.

In accordance to an embodiment, a circuit includes: a first input stage having an input configured to receive an input current, and an output; a first transistor having a control terminal coupled to the output of the first input stage, and a current path; a second transistor having a control terminal and a current path; a current mirror coupled between the current path of the first transistor and the current path of the second transistor; a first output stage having an input coupled to the control terminal of the second transistor, and an output configured to provide an output current; a first resistor coupled between the output of the first input stage and the control terminal of the first transistor; a first capacitor coupled to the first resistor and to the control terminal of the first transistor; and a first feedback path having an output coupled to the first resistor. The first feedback path includes: a buffer having an output coupled to the control terminal of the first transistor, and a second capacitor.

In accordance to an embodiment, a transceiver includes: a first filter having an input and an output; a first mixer having an input and an output, the input of the first mixer coupled to the output of the first filter; a second mixer having an input and an output; and a second filter having an input and an output, the input of the second filter coupled to the output of the second mixer. The first filter includes: a first amplifier having an input coupled to the input of the first filter and an output; a second amplifier having an input coupled to the output of the first amplifier and an output; and a first feedback path coupled between the second amplifier and the input of the first amplifier and including a buffer and a capacitor

### BRIEF DESCRIPTION OF THE DRAWINGS

FIG. 1A shows an example of a current-based device filter.

FIG. 1B shows another example of a current-based device filter.

FIG. 1C shows another example of a current-based device filter.

FIG. 1D shows another example of a current-based device filter.

FIG. 1E shows another example of a current-based device filter.

FIG. 1F shows another example of a current-based device filter.

FIG. 1G shows another example of a current-based device filter.

FIG. 1H shows another example of a current-based device filter.

FIG. 2 shows an example of a cascaded filter including two current-based device filters.

FIG. 3 shows an example of a transceiver.

FIG. 4 shows an example of a buffer.

FIG. 5 shows an example of a current-based mixer.

FIGS. 6A and 6B show an example of two current-based device filters.

FIG. 7 shows an example of a differential transceiver.

### DETAILED DESCRIPTION

Current-based device filters are an important class of electronic circuits that have been developed to meet the needs of modern applications. These filters operate by processing signals as currents rather than voltages, which can offer several advantages in terms of circuit design and implementation.

Current-mode filters are subject to certain limitations in terms of their ability to balance die area and quality factor (Q). Specifically, some current-mode filters use cascaded amplifiers, but filters that employ multiple amplifiers can occupy significant die space, thereby limiting their potential for miniaturization. This is a particular concern in the context of modern integrated circuit design, where reducing die area is crucial to increasing device density and reducing production costs.

Furthermore, the use of multiple amplifiers can also lead to increased power consumption and heat generation, which can compromise the reliability and lifespan of the filter. In contrast, filters optimized for limited space may struggle to achieve sufficient Q, leading to compromised performance in terms of frequency selectivity and stability. The increasing demand for higher data rates and more stringent standards has resulted in a need for improved current-mode filters that can provide a better balance of die area and filter quality.

Thus, a current-based device filter is disclosed having a buffer and a capacitor in a feedback path, which enables the realization of a biquadratic response while minimizing die area compared to other filters. The inclusion of the capacitor in this feedback path allows for improved frequency selectivity and stability, while the use of the buffer reduces out-of-band zeros and ensures a more predictable and desirable frequency response.

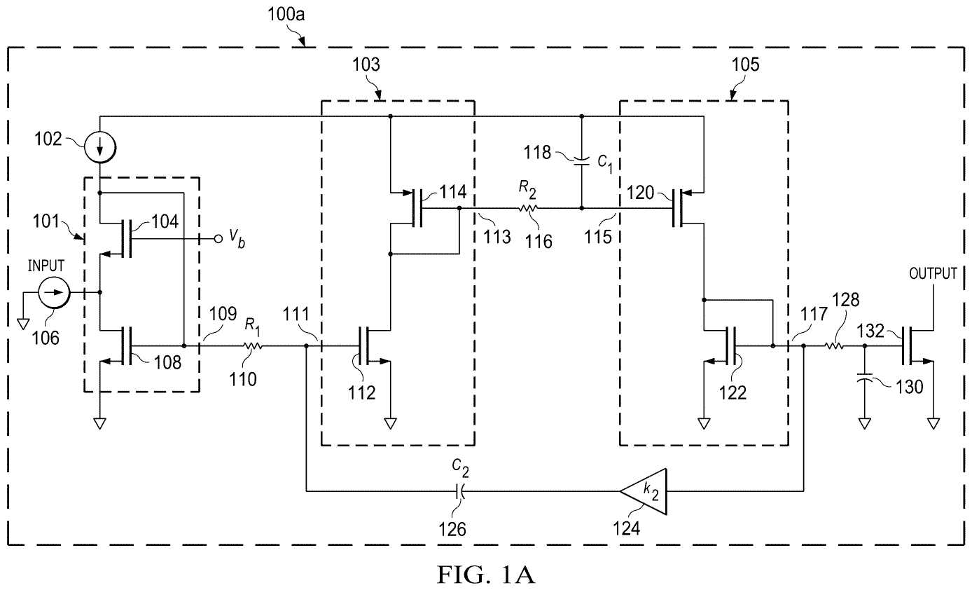

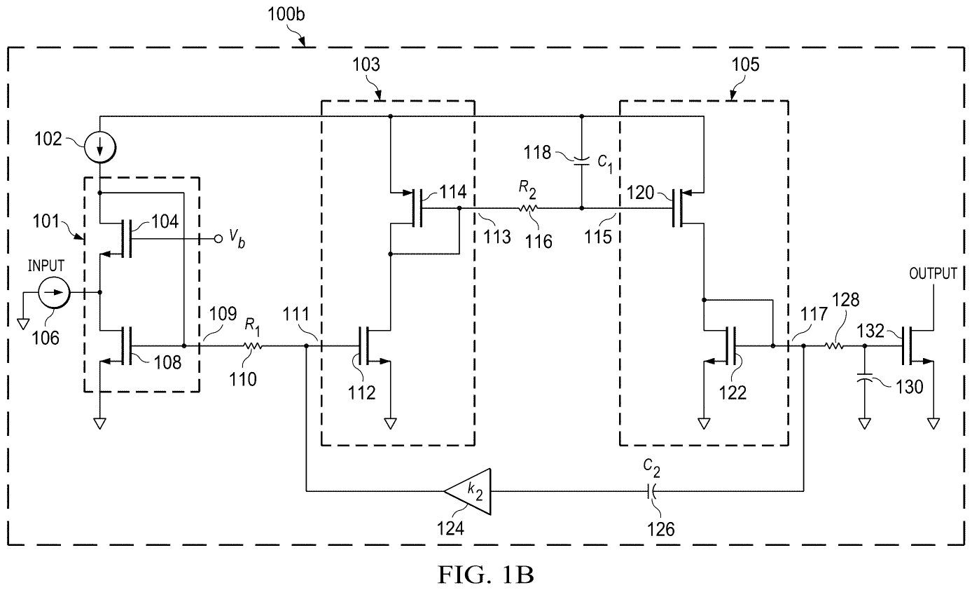

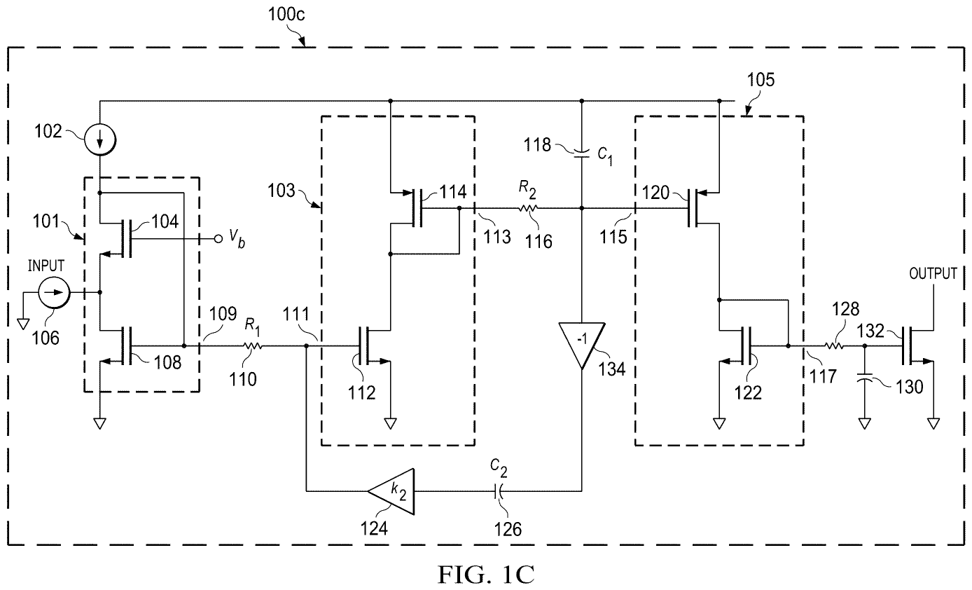

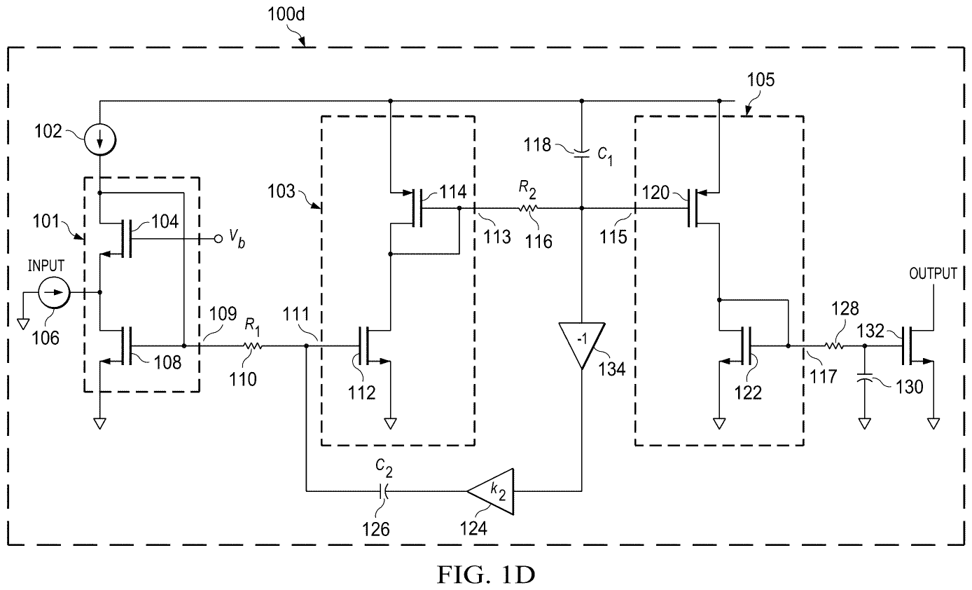

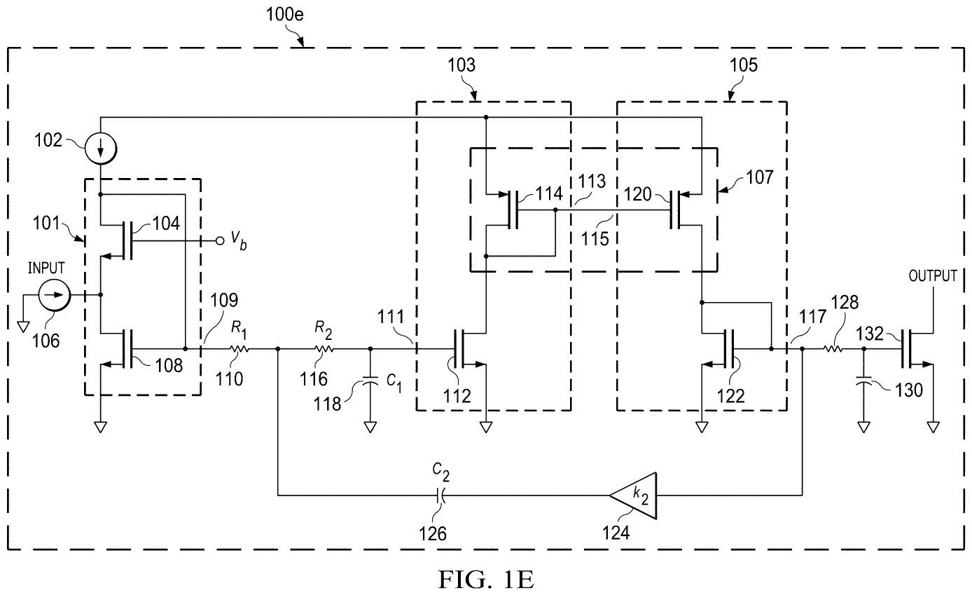

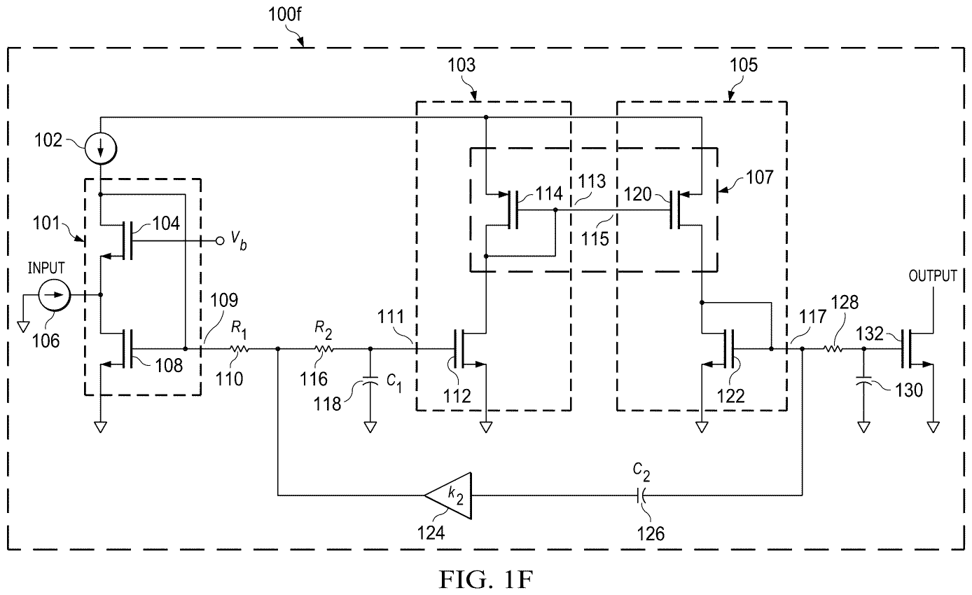

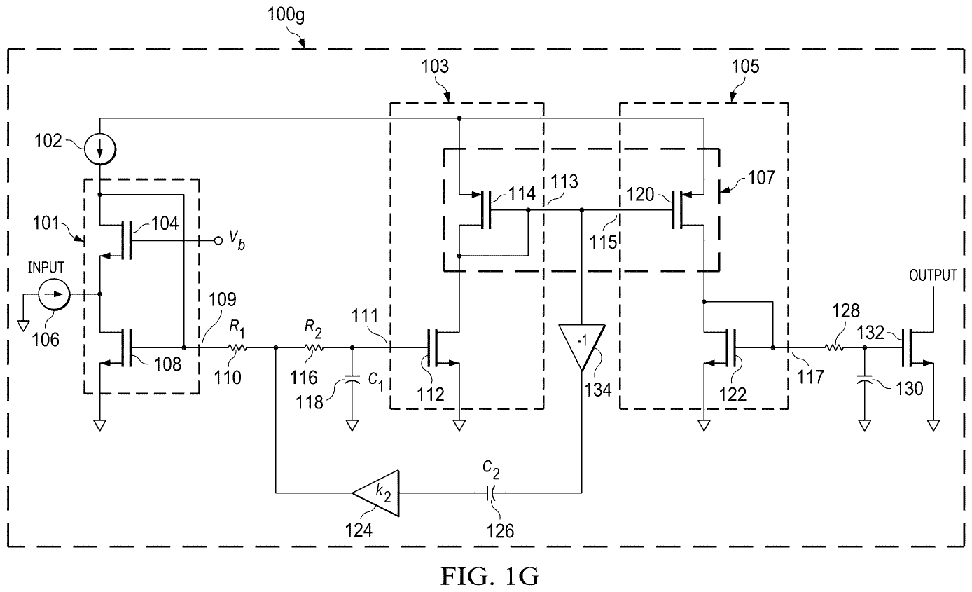

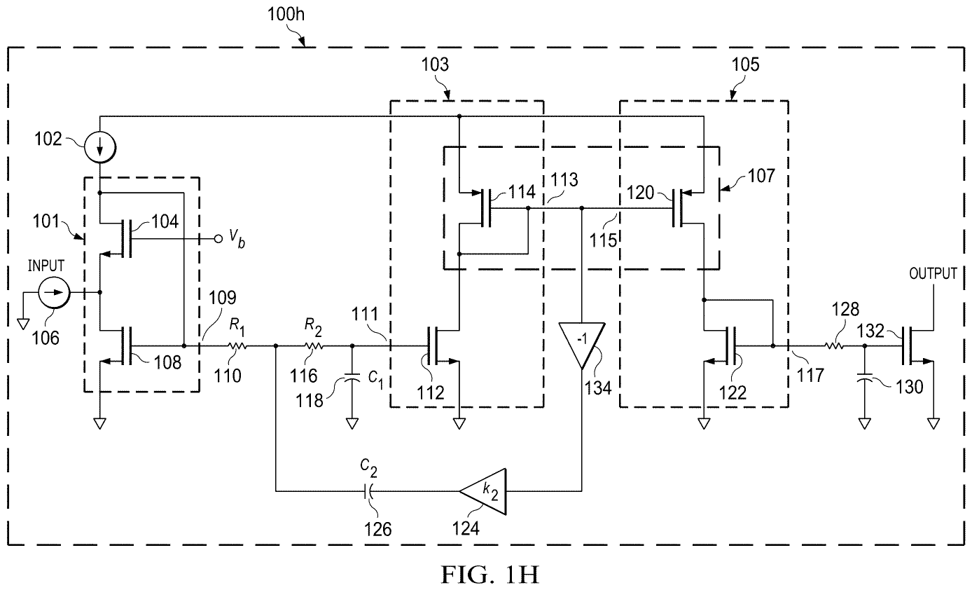

FIG. 1A shows an example current-based device filter 100a that may be integrated in an integrated circuit. The current-based device filter 100a includes an input stage 101, a current source 102, a first amplifier 103, a second amplifier 105, an input 106, and various electronic components connected thereto. Specifically, the input stage 101 includes a first transistor 104 and a second transistor 108. The first amplifier 103 includes a third transistor 112 and a fourth transistor 114. The second amplifier 105 includes a fifth transistor 120 and a sixth transistor 122. Additionally, the current-based device filter 100a includes a buffer 124, a first resistor 110, a second resistor 116, a first capacitor 118, a second capacitor 126, a third resistor 128, a third capacitor 130, and a seventh transistor 132. The first amplifier 103 may be structured to have unity gain, and the second amplifier 105 may be structured to have unity gain. In some cases, the first amplifier 103 may be referred to as a first buffer, and the second amplifier 105 may be referred to as a second buffer.

The input stage 101 has an input 106 configured to receive an input current and an output 109 configured to provide an output current. A supply terminal of the input stage 101 is a first current terminal (e.g., a drain terminal) of the first transistor 104. The current source 102 has a terminal coupled to the first current terminal of the first transistor 104 and biases the input stage 101. The input 106 of the input stage 101 is coupled to a second current terminal (e.g., a source terminal) of the first transistor 104 and is coupled to a first current terminal (e.g., a drain terminal) of the second transistor 108. The output 109 of the input stage 101 is coupled to the first current terminal of the first transistor 104, the control terminal of the second transistor 108, and to a first terminal of the first resistor 110. The control terminal of the first transistor 104 is coupled to an input voltage bias (Vb). The second current terminal (e.g., a source terminal) of the second transistor 108 is coupled to a reference terminal (e.g., ground or VSS).

The first amplifier has an input 111 and an output 113. Within the first amplifier 103, the control terminal of the third transistor 112 is the input 111 of the first amplifier 103. The fourth transistor 114 has a first current terminal coupled to a first current terminal of the third transistor 112 and coupled to the control terminal of the fourth transistor 114. The third transistor 112 has a second current terminal coupled to the reference terminal. The fourth transistor 114 has a second current terminal coupled to a supply terminal (e.g., VDD). The first current terminal of the fourth transistor 114 is the output of the first amplifier 103. The reference terminal may alternatively be referred to as a second supply terminal.

The second resistor 116 has a first terminal coupled to the output 113 of the first amplifier 103 and a second terminal coupled to both a first terminal of the first capacitor 118 and an input 115 of the second amplifier 105. The first capacitor 118 has a second terminal coupled to the supply terminal. A first RC-filter is formed by the second resistor 116 and the first capacitor 118.

Within the second amplifier 105, the fifth transistor 120 has a control terminal that is the input of the second amplifier 105. The fifth transistor 120 has a first current terminal coupled to the supply terminal, and a second current terminal coupled to a first current terminal of the sixth transistor 122. The first current terminal of the sixth transistor 122 is also coupled to the control terminal of the sixth transistor 122. The sixth transistor 122 has a second current terminal coupled to the reference terminal. The output of the second amplifier is the first current terminal and control terminal of the sixth transistor 122.

A feedback path is provided from the control terminal of the sixth transistor 122 to the control terminal of the third transistor 112, and includes a buffer 124 and a second capacitor 126. The buffer has an input coupled to the control terminal of the sixth transistor 122 and an output coupled to one terminal of the second capacitor 126. The second terminal of the second capacitor 126 is coupled to the control terminal of the third transistor 112.

The third resistor 128 is coupled between the control terminal of the sixth transistor 122 and a first terminal of the third capacitor 130, as well as the control terminal of the seventh transistor 132. The second terminal of the third capacitor 130 is coupled to the reference terminal. Additionally, the seventh transistor 132 has its first current terminal coupled to an output terminal and its second current terminal coupled to the reference terminal.

The first transistor 104 and the second transistor 108 are both depicted as n-type transistors. Both the third transistor 112 and the sixth transistor 122 are n-type transistors, while the fourth transistor 114 and the fifth transistor 120 are both p-type transistors. Alternatively, an equivalent circuit utilizing transistors of opposite polarities may be used. The seventh transistor 132 may be designated as an output stage. The resistance and capacitance values of the filters may be varied to achieve a desired filter response. For example, the resistance and capacitance values of the filters may be configured to provide a Butterworth response. The current-based device filter 100a is a third order filter.

The current-based device filter 100a functions as follows. The input stage 101 receives a current input signal from the input 106. The first transistor 104, configured as a common gate amplifier, takes an input current from a low impedance source (e.g., the input 106) and transfers it to an output current (e.g., output 109) with high impedance, effectively buffering the current. Additionally, the second transistor 108 functions similarly to a diode-connected transistor, while the first transistor 104 acts as a current buffer between the drain terminal and gate terminal of the second transistor 108.

The input 111 of the first amplifier 103 is controlled by a voltage provided by the output 109 of the input stage 101, and the output 113 of the first amplifier establishes a voltage that controls transistors 114, 120. The third transistor 112 is configured as a common source amplifier, resulting in an inverted and amplified output signal. The fourth transistor 114 is arranged in a diode-connected configuration. The output 113 of the first amplifier 103 is determined by the transconductance characteristics of both the third transistor 112 and the fourth transistor 114, and exhibits an inversion relative to the input signal on input 111.

The second resistor 116 and the first capacitor 118 function as a filter circuit between the output 113 of the first amplifier 103 and the input 115 of the second amplifier 105. The second resistor 116 and the first capacitor 118 may form a first low-pass filter. Because the first capacitor 118 stores charge, it may be considered a first memory element that provides a first pole to the system.

The second amplifier 105 has an input 115 at the gate terminal of the fifth transistor 120 and has an output 117 coupled to both the drain terminal and gate terminal of the sixth transistor 122. The fifth transistor 120 is configured as a common source amplifier which also inverts the input signal. The inversion characteristic inherent in the fifth transistor 120 effectively negates the inversion produced by the first amplifier 103. The sixth transistor 122 is implemented in a diode-connected configuration. Consequently, the second amplifier 105 exhibits a structural similarity to the first amplifier 103, employing a common source amplifier and a diode-connected transistor, with the distinction being the polarity of the respective transistors. If the transistors within the first amplifier 103 and the second amplifier 105 were made identical, the gain characteristics of the amplifiers would exhibit a reciprocal relationship. For example, if the first amplifier 103 possesses a gain denoted as k1, and the second amplifier 105 exhibits a gain represented by k2, then k1=1/k2. This reciprocal relationship provides a unity gain of the input 111 at the first amplifier 103 to the output 117 of the second amplifier 105.

The output 117 of the second amplifier 105 is coupled to the feedback path comprising the buffer 124 and the second capacitor 126. The second capacitor 126 introduces an additional pole to the filter, enabling a biquadratic response. Further, the buffer 124 provides a low impedance source for the second capacitor 126.

The output signal from the output 117 of the second amplifier 105 is further directed to a second RC filter comprising the third resistor 128 and the third capacitor 130. This second RC filter may also implement a low-pass filter. The output of this second RC filter, generated at the third resistor and third capacitor 130, is coupled to the gate terminal of the seventh transistor 132 in a common source amplifier configuration. The seventh transistor 132 may also be designated as an output stage, and alternative suitable output stages may be employed.

The current-based device filter 100a offers several distinct advantages. The inclusion of the feedback path incorporating the second capacitor 126 establishes a second memory element, introducing an additional pole into the system. This elevates the filter's frequency selectivity and quality factor (Q), enabling sharper frequency response and enhanced signal isolation. Additionally, the buffer 124 increases the output impedance that the feedback path sees from the output 117 of the second amplifier 105. This operational characteristic minimizes the potential for out-of-band zeros typically introduced by feedback loops, ensuring a more predictable and desirable frequency response. Furthermore, the minimized footprint achieved through the integrated design reduces die area requirements compared to traditional multi-amplifier filters, contributing to increased device density and reduced production costs.

Another advantage of the current-based device filter 100a is its ability to utilize device capacitors (e.g., poly-silicon capacitors) instead of traditional metal capacitors. For example, capacitors 118, 126, and 130 may all be device capacitors. Device capacitors may be formed by forming a dielectric layer (e.g., a semiconductor oxide) on a semiconductor substrate and forming a polycrystalline semiconductor layer on the dielectric layer. In contrast, metal capacitors may be formed in the routing layers of a device using interlayer dielectric (ILD) material as a dielectric layer between conductor (e.g., metal) features. Compared to ILD metal capacitors, the device capacitors can utilize less horizontal area due to the vertical thickness of the dielectric layer being less than the vertical thickness of the ILD material of an ILD metal capacitors. The current-based device filter 100a can take advantage of the smaller device capacitors even where they are more fragile than ILD metal capacitors because the feedback path is configured to receive the input signal at unity-gain, thereby avoiding high voltage swings that could potentially damage the dielectric in device capacitors. Although, in a given example, some or all of capacitors 118, 126, and 130 may all be device capacitors, the integrated circuit that the current-based device filter 100a is integrated into may also utilize ILD metal capacitors in other portions of the device.

Although the transistors in FIG. 1A are illustrated as metal oxide semiconductor field effect transistors (MOSFETs), other types of transistors may be used. For example, in FIG. 1A, each MOSFET has a source/drain (which is an example of a first current terminal), a drain/source (which is an example of a second current terminal), and a gate terminal (which is an example of a control terminal). Bipolar junction transistors (BJT), FinFETs, junction FETs (JFETs), and other transistors could be used in place of the illustrated MOSFETS. BJTs include a collector/emitter (which is an example of a first current terminal), an emitter/collector (which is an example of a second current terminal), and a base (which is an example of a control terminal).

FIGS. 1B-1H illustrate alternatives examples of current-based device filters 100b-100h where various modifications have been made to the structure of the current-based device filter 100a shown in FIG. 1A. Except where noted, the elements of FIGS. 1B-1H are similar to their counterparts in FIG. 1A.

FIG. 1B depicts a current-based device filter 100b, where the configuration of the feedback path has been modified by interchanging the positions of the buffer 124 and the second capacitor 126. Specifically, the first terminal of the second capacitor 126 is now coupled to the control terminal of the sixth transistor 122, while the second terminal of the second capacitor 126 is coupled to the input of the buffer 124. The output of the buffer 124 is then coupled to the control terminal of the first amplifier 103. This configuration enables an alternative implementation of the current-based device filter 100b, which retains the benefits of a biquadratic response and improved frequency selectivity while offering flexibility in design and layout.

FIG. 1C depicts a current-based device filter 100c, where the feedback path originates from the input of the second amplifier 105 rather than the output thereof. To negate the inversion introduced by the first amplifier 103, an inverter 134 is incorporated into the feedback path. Specifically, the inverter 134 has an input coupled to the input of the second amplifier 105 and an output coupled to a first terminal of the second capacitor 126. The second capacitor 126 has a second terminal coupled to the input of the buffer 124, while the output of the buffer 124 is coupled to the input of the first amplifier 103.

FIG. 1D illustrates a current-based device filter 100d, where the feedback path originates from the input of the second amplifier 105. In this configuration, the inverter 134 has an input terminal coupled to the input of the second amplifier 105 and an output terminal coupled to the input of the buffer 124. The output of the buffer 124 is coupled to a first terminal of the second capacitor 126, while the second terminal of the second capacitor 126 is coupled to the input of the first amplifier 103. Additionally, the inverting and buffering may be combined into a single circuit block.

FIGS. 1E-1H show alternative examples of current-based device filters 100e-100h, where the second resistor 116 and the first capacitor 118 have been relocated between the output of the feedback path and the input of the first amplifier 103.

FIG. 1E shows a current-based device filter 100e, where the second resistor 116 and the first capacitor 118 are positioned between an output of the feedback path and the input of the first amplifier 103. As a result, the combination of fourth transistor 114 and fifth transistor now forms a current mirror 107. The current mirror 107 is coupled between the current path terminals of the third transistor 112 and the sixth transistor 122. The first resistor 110 has a terminal coupled to a first terminal of the second resistor 116, while the second resistor's second terminal is coupled to a first terminal of the first capacitor 118 and to the input of the first amplifier 103. The first capacitor 118 also has a second terminal coupled to a reference terminal.

FIG. 1F shows a current-based device filter 100f, which is similar to the current-based device filter 100E except that the buffer 124 and the second capacitor 126 have been reversed in position. In this configuration, the second capacitor 126 has a first terminal coupled to the output of the second amplifier 105 and a second terminal coupled to the input of the buffer 124. The buffer's output is coupled to the first terminal of the second resistor 116.

FIG. 1G shows a current-based device filter 100g such that the feedback path is from the input of the second amplifier 105. In this example, the feedback path also includes an inverter 134. The inverter 134 has an input coupled to the input of the second amplifier and an output coupled to the first terminal of the second capacitor 126. The second capacitor has a second terminal coupled to the input of the buffer 124. The buffer has an output coupled to the first terminal of the second resistor 116.

FIG. 1H shows a current-based device filter 100h such that the feedback path is from the input of the second amplifier 105 and includes the inverter 134. The inverter 134 has an input coupled to the input of the second amplifier 105 and an output coupled to the input of the buffer 124. The buffer 124 has an output coupled to a first terminal of the second capacitor 126. The second capacitor 126 has an output coupled to the first terminal of the second resistor 116.

In FIGS. 1A-1H, the terminals of the transistors may be referred to as current terminals, current path terminals, or be specific to a transistor implementation. For example, individual terminals may be a source terminal, a drain terminal, or a gate terminal. Alternatively, the terminals may be referred to as a current path between the source terminal and the drain terminal, and also include a control terminal. Additionally, the transistors shown are metal-oxide field effect transistors (MOSFETS), and other transistor technologies may be used such as junction field effect transistors (JFETS), bipolar junction transistors (BJTS), along with their respective terminal names.

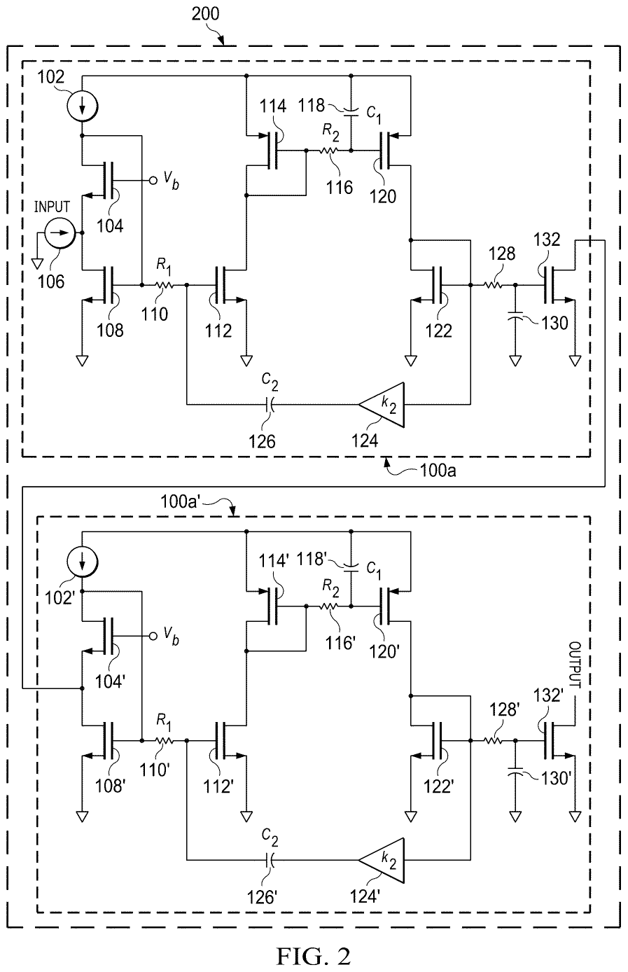

FIG. 2 illustrates an exemplary example of a cascaded filter configuration 200, where multiple current-based device filters are coupled together to form a high-performance filtering system. Specifically, as shown in FIG. 2, a first current-based device filter 100a and a second current-based device filter 100a′ are cascaded together, with the output of the first filter 100a being coupled to the input of the second filter 100a′. Further examples replace one or more of first device filter 100a and second device filter 100a′ with any of device filters 100b-100h. These configurations enables the realization of complex filtering functions through the combination of multiple stages, thereby providing enhanced signal processing capabilities. The use of a cascaded filter configuration offers several advantages over traditional single-stage filters such the realization of higher-order filtering functions, which are essential in many applications requiring precise signal processing.

In addition to the exemplary example shown in FIG. 2, more stages of filters can be added to the cascaded configuration. For example, while only two filters are depicted in FIG. 2, there may be between 2-8 stages, or between 3-4 stages, thereby enabling the realization of a wide range of filtering functions and applications.

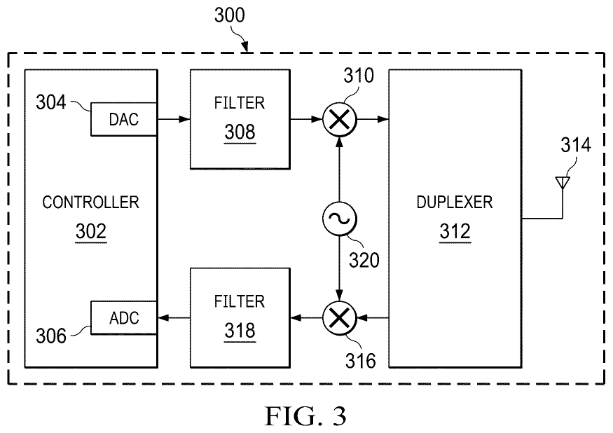

FIG. 3 illustrates an example schematic of a transceiver 300. The transceiver 300 includes a controller 302, a first filter 308, a first mixer 310, a duplexer 312, an antenna 314, a second mixer 316, a second filter 318, and a local oscillator 320. The controller comprises a digital-to-analog (DAC) converter 304, and an analog-to-digital (ADC) converter 306. The transceiver 300 may be an ultrawide-band (UWB) transceiver.

The DAC 304 has an output coupled to an input of the first filter 308, which may include one or more of the current-based device filters 100a-100h. The first filter 308 has an output coupled to the first mixer 310. The first mixer also receives an input from the local oscillator 320 and provides an output to the duplexer 312. The duplexer has an output to the antenna 314 and an output to the second mixer 316. The second mixer has another input from the local oscillator 320 and provides an output to an input of the second filter 318, which may also include one or more of the current-based device filters 100a-100h. The second filter 318 has an output coupled to the ADC 306.

The transceiver 300 operates by a sending a signal at baseband to the first filter 308. The first filter 308 filters the signal and provides it to the first mixer 310, which multiplies the filtered signal with the input from the local oscillator 320 to produce an output at radio-frequency. The output signal will then go to the duplexer 312 which will switch the input/output from the antenna 314. This process enables efficient transmission of signals while minimizing interference.

Alternatively, when receiving a signal, the antenna 314 obtains a signal, and the duplexer 312 receives it and sends it to the second mixer 316. The second mixer 316 also receives an input from the local oscillator 320 and provides an output to the second filter 318. After passing through the second mixer 316, the signal is now at baseband. The second filter 318 then filters the signal and provide an output to the ADC 306 for processing by the controller 302.

The use of current-based device filters 100a-100h in the first filter 308 and the second filters 318 enables the transceiver to achieve improved filtering capabilities. These filters provide enhanced selectivity and rejection of unwanted signals, allowing the system to more effectively reject out-of-band interference and improve its ability to detect weak signals. This results in improved overall performance and reliability of the transceiver.

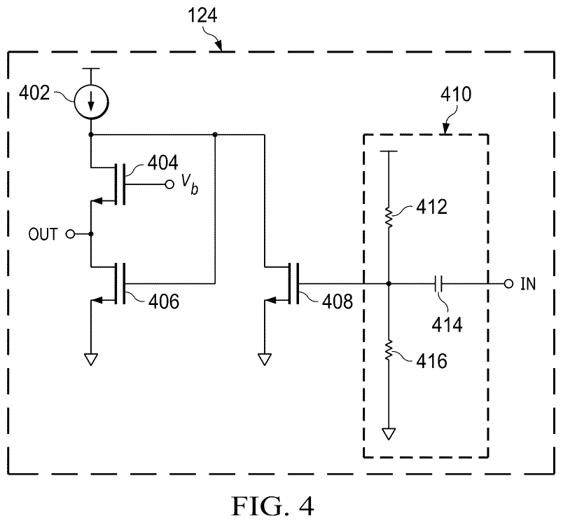

FIG. 4 illustrates an example of the buffer 124. The buffer 124 includes a current source 402, a first transistor 404, a second transistor 406, and a third transistor 408. Additionally, a biasing circuit 410 may be included to provide further functionality. The input signal is provided from the right-hand side, while the output is taken from the left-hand side for consistency with FIGS. 1A-1H.

The third transistor 408 has a control terminal coupled to the output of the biasing circuit 410. The biasing circuit 410 has an input coupled to the input of the buffer 124. The third transistor 408 is in a common source configuration such that the drain terminal (first current terminal) is the output that is amplified, and the source terminal (second current terminal) is coupled to the reference terminal. The first current terminal of the third transistor 408 is coupled to the first current terminal of the first transistor 404, the current source 402, and the control terminal of the second transistor 406. The second current terminal of the first transistor 404 is coupled to the first current terminal of the second transistor 406. The second current terminal of the first transistor 404 is the output of the buffer. The first transistor 404 has a control terminal coupled to a voltage bias (Vb) input. The second transistor 406 has a second current terminal coupled to the reference terminal.

The biasing circuit 410 includes a first resistor 412, a second resistor 416 and a first capacitor 414. The first capacitor 414 has a first terminal that is coupled to the input of the biasing circuit 410. The first capacitor 414 has a second terminal that is coupled to the output of the current biasing circuit, a first terminal of the first resistor 412, and a first terminal of the second resistor 416. The first resistor 412 has a second terminal coupled to the supply terminal. The second resistor has a second terminal coupled to the reference terminal. The biasing circuit 410 biases the third transistor 408 to operate in saturation mode. The biasing circuit may be absent when used in examples 100a, 100d, 100e, and 100h where the input to the buffer 124 is coupled to a gate of a transistor, so the input to the buffer 124 is properly biased. Additionally, the first capacitor 414 may be removed because the second capacitor 126 is already in the feedback path.

Because the first transistor 404 receives a relatively stable gate voltage, the first transistor 404 functions as a resistor in this circuit. The first transistor 404 along with the current source 402 function to set a bias point for the transistors. The second transistor 406 functions similarly to a diode-connected transistor. The third transistor 408 functions to amplify the input signal. An advantage of this buffer configuration is that it combines biasing, current handling, and amplification into a single stage.

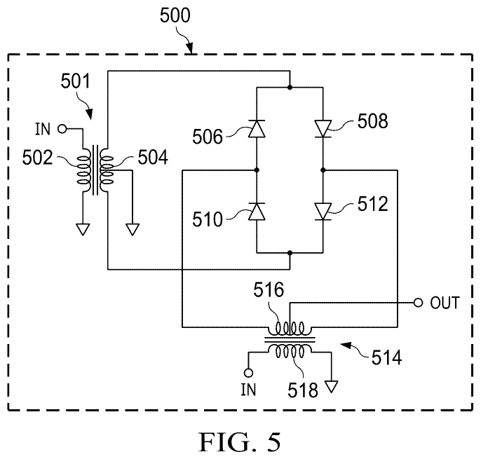

FIG. 5 illustrates an example of a current-based mixer 500 that may be coupled to the output of the current-based device filters 100a-100h. The current based mixer 500 comprises a first transformer 501, a second transformer 514, a first diode 506, a second diode 508, a third diode 510, and a fourth diode 512.

The first transformer 501 includes a primary coil 502 and a secondary coil 504. The second transformer includes a primary coil 518 and a secondary coil 516. The primary coil 502 has a first terminal that is coupled to an input, which may be the output of the current-based device filters 100a-100h or a local oscillator. The second terminal of the primary coil 502 is coupled to a reference terminal. The secondary coil 504 is coupled between the first diode 506 and the third diode 510, as well as between the second diode 508 and the fourth diode 512. Additionally, the secondary coil 504 has a center tap coupled to ground.

The primary coil 518 of the second transformer 514 has a first terminal that is coupled to another input, which may be the output of the current-based device filters 100a-100h or a local oscillator. A second terminal of the primary coil 518 is coupled to the reference terminal. The secondary coil 516 of the second transformer 514 is coupled between the first diode 506 and the second diode 508, as well as between the third diode 510 and the fourth diode 512. Furthermore, the secondary coil 516 has a center tap coupled to the output of the current-based mixer.

The first diode 506 has a cathode coupled to the anode of the second diode 508. The second diode 508 has a cathode coupled to the anode of the fourth diode 512. The fourth diode 512 has a cathode coupled to the anode of the third diode 510. The third diode has a cathode coupled to the anode of the first diode 506.

The first transformer 501 and the second transformer 514 function as baluns to magnetically couple the inputs at a desired impedance. The diodes function to provide a non-linear relationship that approximates multiplication.

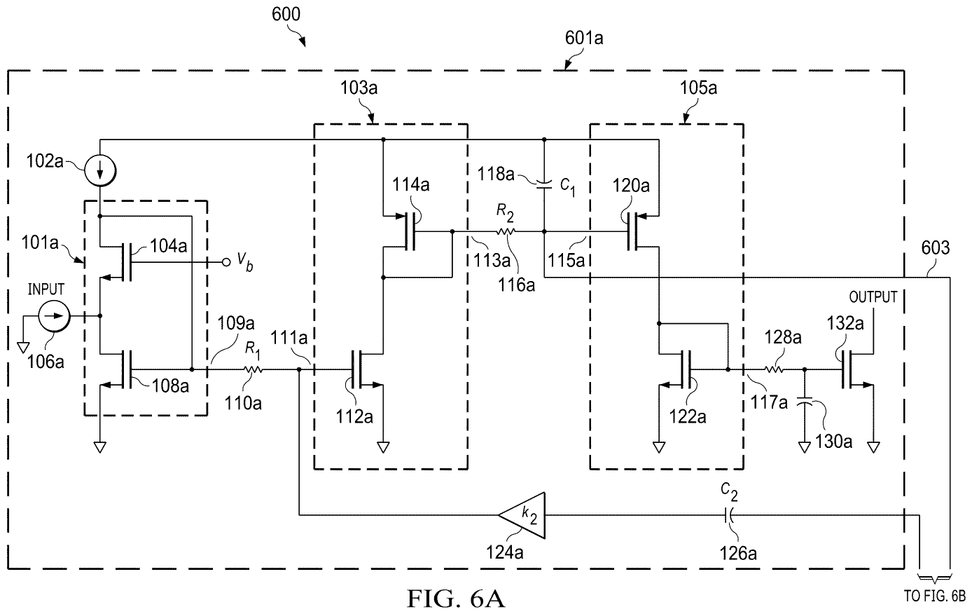

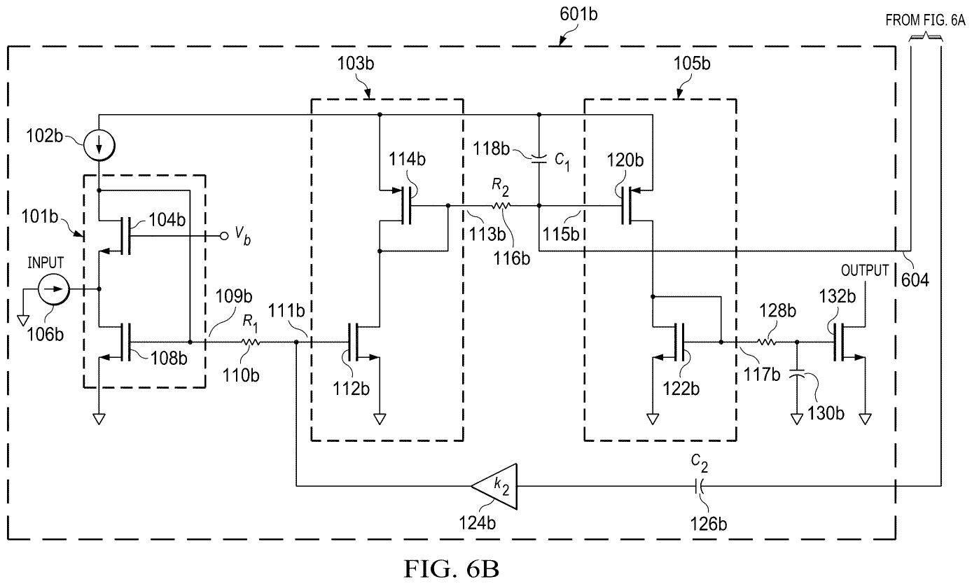

FIGS. 6A and 6B show an example of a pseudo differential filter 600 that comprises two current-based device filters 601a, 601b based on the principles of FIGS. 1A-1H described above. In this example, differential signaling may be used. For example, the first current-based device filter 601a may receive a first signal at input 106a, and the second current-based device filter 601b may receive a second signal at input 106b that is an inverted version of the first signal. The first current-based device filter 601a is shown being similar to the current-based device filter 100c with the change being that the feedback path 604 is from input 115b of the second current-based device filter 601b. Similarly, the feedback path 603 of the second current-based device filter 601b is from input 115a of the first current-based device filter. This configuration advantageously reduces the number of circuit elements by removing the inverters that were previously shown in FIG. 3C. Additionally, the first current-based device filter 601a may be any of the examples 100a-100h that are changed to have the mentioned feedback path. Similarly, the second current-based device filter 601b may be any of the examples 100a-100h that are changed to have the mentioned feedback paths.

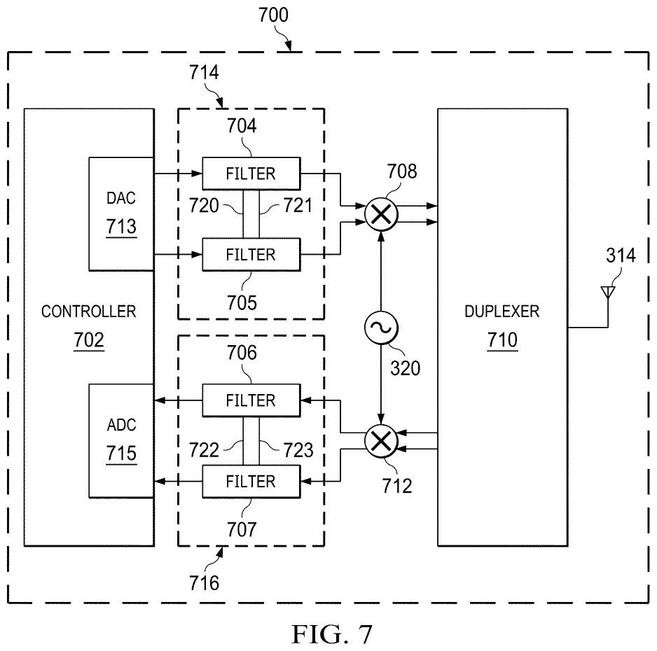

FIG. 7 shows an example of a differential-based transceiver 700. The differential-based transceiver 700 includes a controller 702, a first pseudo differential filter 714, a first mixer 708, a duplexer 710, an antenna 314, a local oscillator 320, a second mixer 712, and a second pseudo differential filter 716. The controller 702 comprises a first digital-to-analog converter (DAC) 713, and a first analog-to-digital converter (ADC) 715. The first pseudo differential filter 714 comprises a first filter 704 and a second filter 705. The second pseudo differential filter 716 comprises a third filter 706 and a fourth filter 707. The first pseudo differential filter 714 and the second pseudo differential filter 716 may each be the pseudo differential filter 600 shown in FIG. 6.

The first DAC 713 has outputs coupled to an input of the first filter 704 and the input of the second filter 705. The first filter 704 and the second filter 705 may be the current-based device filters 601a-601b as shown in FIG. 6. Thus, the first filter 704 may be coupled to the second filter 705 through feedback paths 720-721. The first filter 704 has an output coupled to the first mixer 708. The second filter 705 has an output coupled to the first mixer 708. The local oscillator 320 has an output coupled to the first mixer 708. The first mixer 708 has two outputs coupled to the duplexer 710. The duplexer has an output coupled to the antenna 314. The coupling between the duplexer 710 and the antenna 314 may use differential signaling. The duplexer 710 has two outputs coupled to the second mixer 712. The local oscillator 320 has a second output coupled to the second mixer 712, The second mixer 712 has a first output coupled to the third filter 706, and has a second output coupled to the fourth filter 707. The third filter 706 and the fourth filter 707 may also be the current-based device filters 601a-601b shown in FIG. 6. Thus, the third filter 706 and the fourth filter 707 may be coupled through feedback paths 722-723. The third filter 706 has an output coupled to the first ADC 715. The fourth filter 707 has an output couple to the first ADC 715.

The differential-based transceiver 700 advantageously uses differential signaling throughout the transmit and the receive path. The differential signaling allows for an increase in common-mode rejection, thereby improving signal quality.

Example embodiments of the present disclosure are summarized here. Other embodiments can also be understood from the entirety of the specification and the claims filed herein.

Example 1. A circuit including: a first input stage having an input configured to receive an input current, and an output; a first amplifier having an input coupled to the output of the first input stage, and an output; a second amplifier having an input coupled to the output of the first amplifier, and an output; a first resistor coupled between the output of the first amplifier and the input of the second amplifier; a first capacitor coupled to the first resistor and to the input of the second amplifier; a first output stage having an input coupled to the output of the second amplifier, and an output configured to provide an output current; and a first feedback path coupled between the second amplifier and the input of the first amplifier, the first feedback path including: a buffer having an output coupled to the input of the first amplifier, and a second capacitor.

Example 2. The circuit of example 1, where the input of the first feedback path is coupled to the output of the second amplifier.

Example 3. The circuit of one or more of examples 1 or 2, where the first resistor and the first capacitor form a first low-pass filter, where the input of the first feedback path is coupled to an output of the first low-pass filter.

Example 4. The circuit of one or more of examples 1 to 3, where the second capacitor is coupled between an input of the buffer and the second amplifier.

Example 5. The circuit of one or more of examples 1 to 4, where the second capacitor is coupled between the output of the buffer and the input of the first amplifier.

Example 6. The circuit of one or more of examples 1 to 5, where the first input stage includes: a first transistor having a current path coupled between the input of the first input stage and a reference terminal, and a control terminal coupled to the input of the first amplifier; and a second transistor having a first current path terminal coupled to a supply terminal, and a second input terminal coupled to the input of the first input stage.

Example 7. The circuit of one or more of examples 1 to 6, where the first current path terminal of the second transistor is coupled to the input of the first amplifier via a second resistor.

Example 8. The circuit of one or more of examples 1 to 7, where the first output stage includes a first transistor having a current path coupled to the output of the first output stage, and a control terminal coupled to the output of the second amplifier.

Example 9. The circuit of one or more of examples 1 to 8, further including a low-pass filter coupled between the output of the second amplifier and the input of the first output stage.

Example 10. The circuit of one or more of examples 1 to 9, where the low-pass filter includes: a second resistor coupled between the output of the second amplifier and the input of the first output stage; and a third capacitor coupled to the second resistor.

Example 11. The circuit of one or more of examples 1 to 10, where the first amplifier includes: a first transistor having a control terminal coupled to the output of the first input stage; and a second transistor having a current path terminal coupled to a current path terminal of the first transistor, and a control terminal coupled to the first resistor and to the current path terminal of the second transistor.

Example 12. The circuit of one or more of examples 1 to 11, where the second amplifier includes: a first transistor having a control terminal coupled to the first resistor and to the first capacitor; and a second transistor having a current path terminal coupled to a current path terminal of the first transistor, and a control terminal coupled to the input of the first output stage and to the current path terminal of the second transistor.

Example 13. The circuit of one or more of examples 1 to 12, where the buffer includes: a first transistor having a control terminal coupled to an input of the buffer, and first and second current path terminals; a second transistor having a first current path terminal coupled to the first current path terminal of the first transistor, and a second current path terminal coupled to the output of the buffer; and a third transistor having a first current path terminal coupled to the output of the buffer, and a control terminal coupled to the first current path terminal of the first transistor.

Example 14. The circuit of one or more of examples 1 to 13, where the buffer further includes a current source coupled to the first current path terminal of the first transistor.

Example 15. The circuit of one or more of examples 1 to 14, further including: a second input stage having an input coupled to the output of the first output stage, and an output; a third amplifier having an input coupled to the output of the second input stage, and an output; a fourth amplifier having an input coupled to the output of the third amplifier, and an output; a second resistor coupled between the output of the third amplifier and the input of the fourth amplifier; a third capacitor coupled to the second resistor and to the input of the fourth amplifier; a second output stage having an input coupled to the output of the fourth amplifier, and an output; and a second feedback path coupled between the fourth amplifier and the input of the third amplifier, the second feedback path including: a second buffer having an output coupled to the input of the third amplifier, and a fourth capacitor.

Example 16. The circuit of one or more of examples 1 to 15, further including a mixer having an output coupled to the input of the first input stage.

Example 17. The circuit of one or more of examples 1 to 16, further including a mixer having an input coupled to the output of the first output stage.

Example 18. The circuit of one or more of examples 1 to 17, further including a filter that includes the first input stage, the first and second amplifiers, and the first output stage, where the filter is configured to have a Butterworth response.

Example 19. The circuit of one or more of examples 1 to 18, where the circuit is integrated in an integrated circuit.

Example 20. The circuit of one or more of examples 1 to 19, where the first and second capacitors are device capacitors of the integrated circuit, the integrated circuit further including a metal capacitor.

Example 21. A circuit including: a first input stage having an input configured to receive an input current, and an output; a first transistor having a control terminal coupled to the output of the first input stage, and a current path; a second transistor having a control terminal and a current path; a current mirror coupled between the current path of the first transistor and the current path of the second transistor; a first output stage having an input coupled to the control terminal of the second transistor, and an output configured to provide an output current; a first resistor coupled between the output of the first input stage and the control terminal of the first transistor; a first capacitor coupled to the first resistor and to the control terminal of the first transistor; and a first feedback path having an output coupled to the first resistor, the first feedback path including: a buffer having an output coupled to the control terminal of the first transistor, and a second capacitor.

Example 22. The circuit of example 21, where an input of the first feedback path is coupled to the control terminal of the second transistor.

Example 23. The circuit of one or more of examples 21 or 22, where an input of the first feedback path is coupled to a control terminal of a third transistor of the current mirror.

Example 24. The circuit of one or more of examples 21 to 23, where the second capacitor is coupled between an input of the buffer and the current mirror.

Example 25. The circuit of one or more of examples 21 to 24, where the second capacitor is coupled between the output of the buffer and the first resistor.

Example 26. The circuit of one or more of examples 21 to 25, where the first input stage includes: a third transistor having a current path coupled between the input of the first input stage and a reference terminal, and a control terminal coupled to the control terminal of the first transistor; and a fourth transistor having a first current path terminal coupled to a supply terminal, and a second current path terminal coupled to the input of the first input stage.

Example 27. The circuit of one or more of examples 21 to 26, where the first current path terminal of the fourth transistor is coupled to the control terminal of the first transistor via the first resistor and via a second resistor.

Example 28. The circuit of one or more of examples 21 to 27, where the first output stage includes a third transistor having a current path coupled to the output of the first output stage, and a control terminal coupled to the current path of the second transistor.

Example 29. The circuit of one or more of examples 21 to 28, further including a low-pass filter coupled between the current path of the second transistor and the input of the first output stage.

Example 30. The circuit of one or more of examples 21 to 29, where the low-pass filter includes: a second resistor coupled between the current path of the second transistor and the input of the first output stage; and a third capacitor coupled to the second resistor.

Example 31. The circuit of one or more of examples 21 to 30, where the buffer includes: a third transistor having a control terminal coupled to an input of the buffer, and first and second current path terminals; a fourth transistor having a first current path terminal coupled to the first current path terminal of the third transistor, and a second current path terminal coupled to the output of the buffer; and a fifth transistor having a first current path terminal coupled to the output of the buffer, and a control terminal coupled to the first current path terminal of the third transistor.

Example 32. The circuit of one or more of examples 21 to 31, where the buffer further includes a current source coupled to the first current path terminal of the first transistor.

Example 33. The circuit of one or more of examples 21 to 32, further including: a second input stage having an input coupled to the output of the first output stage, and an output; a third transistor having a control terminal coupled to the output of the second input stage, and a current path; a fourth transistor having a control terminal and a current path; a second current mirror coupled between the current path of the third transistor and the current path of the fourth transistor; a second output stage having an input coupled to the control terminal of the fourth transistor, and an output; a second resistor coupled between the output of the second input stage and the control terminal of the third transistor; a third capacitor coupled to the second resistor and to the control terminal of the third transistor; and a second feedback path coupled to the control terminal of the third transistor, the second feedback path including: a second buffer having an output coupled to the control terminal of the third transistor, and a fourth capacitor.

Example 34. The circuit of one or more of examples 21 to 33, further including a mixer having an input coupled to the output of the first output stage.

Example 35. The circuit of one or more of examples 21 to 34, further including a filter that includes the first input stage, the first and second transistors, the current mirror, and the first output stage, where the filter is configured to have a Butterworth response.

Example 36. The circuit of one or more of examples 21 to 35, where the filter is a third order filter.

Example 37. The circuit of one or more of examples 21 to 36, where the circuit is integrated in an integrated circuit.

Example 38. The circuit of one or more of examples 21 to 37, where the first and second capacitors are device capacitors of the integrated circuit, the integrated circuit further including a metal capacitor.

Example 39. The circuit of one or more of examples 21 to 38, further including a mixer having an output coupled to the input of the first input stage.

Example 40. The circuit of one or more of examples 21 to 39, where the first feedback path is coupled from a control terminal of a third transistor of the current mirror to the first resistor.

Example 41. The circuit of one or more of examples 21 to 40, where the first feedback path is coupled from the current path of the second transistor to the first resistor.

Example 42. The circuit of one or more of examples 21 to 41, where an input of the buffer is coupled to the current path of the second transistor, and where the second capacitor has a terminal coupled to the first resistor.

Example 43. The circuit of one or more of examples 21 to 42, where the second capacitor has a terminal coupled to the current path of the second transistor, and where the buffer has an output coupled to the first resistor.

Example 44. A transceiver including: a first filter having an input and an output; a first mixer having an input and an output, the input of the first mixer coupled to the output of the first filter; a second mixer having an input and an output; and a second filter having an input and an output, the input of the second filter coupled to the output of the second mixer, where the first filter includes:

Example 45. The transceiver of example 44, further including: a duplexer having a first terminal, and a second terminal, where the first terminal of the duplexer is coupled to the output of the first mixer, and where the input of the second mixer is coupled to the second terminal of the duplexer.

Example 46. The transceiver of one or more of examples 44 or 45, where the second filter includes a third amplifier having an input and an output, a fourth amplifier having an input and an output, and a second feedback path from the output of the fourth amplifier to the input of the third amplifier and including a second buffer and a second capacitor in series, where the input of the third amplifier is coupled to the output of the second filter, and where the output of the third amplifier is coupled to the input of the second amplifier.

Example 47. The transceiver of one or more of examples 44 to 46, further including: an analog-to-digital converter (ADC) having an input coupled to the output of the second filter; and a digital-to-analog converter (DAC) having an output coupled to the input of the first filter.

Example 48. The transceiver of one of examples 44 to 47, where the transceiver is an ultrawide-band (UWB) transceiver.

The methods are illustrated and described above as a series of acts or events, but the illustrated ordering of such acts or events is not limiting. For example, some acts or events may occur in different orders and/or concurrently with other acts or events apart from those illustrated and/or described herein. Also, some illustrated acts or events are optional to implement one or more aspects or embodiments of this description. Further, one or more of the acts or events depicted herein may be performed in one or more separate acts and/or phases. In some embodiments, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are illustrated and/or described herein, other transistors (or equivalent switching devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero. Modifications are possible in the described examples, and other implementations are possible, within the scope of the claims.

What is claimed is:

1. A circuit comprising:
a first input stage having an input configured to receive an input current, and an output;
a first amplifier having an input coupled to the output of the first input stage, and an output;
a second amplifier having an input coupled to the output of the first amplifier, and an output;
a first resistor coupled between the output of the first amplifier and the input of the second amplifier;
a first capacitor coupled to the first resistor and to the input of the second amplifier;
a first output stage having an input coupled to the output of the second amplifier, and an output configured to provide an output current; and
a first feedback path coupled between the second amplifier and the input of the first amplifier, the first feedback path including:
a buffer having an output coupled to the input of the first amplifier, and
a second capacitor.

2. The circuit of claim 1, wherein the input of the first feedback path is coupled to the output of the second amplifier.

3. The circuit of claim 1, wherein the first resistor and the first capacitor form a first low-pass filter, wherein the input of the first feedback path is coupled to an output of the first low-pass filter.

4. The circuit of claim 1, wherein the second capacitor is coupled between an input of the buffer and the second amplifier.

5. The circuit of claim 1, wherein the second capacitor is coupled between the output of the buffer and the input of the first amplifier.

6. The circuit of claim 1, wherein the first input stage comprises:
a first transistor having a current path coupled between the input of the first input stage and a reference terminal, and a control terminal coupled to the input of the first amplifier; and
a second transistor having a first current path terminal coupled to a supply terminal, and a second input terminal coupled to the input of the first input stage.

7. The circuit of claim 6, wherein the first current path terminal of the second transistor is coupled to the input of the first amplifier via a second resistor.

8. The circuit of claim 1, wherein the first output stage comprises a first transistor having a current path coupled to the output of the first output stage, and a control terminal coupled to the output of the second amplifier.

9. A circuit comprising:
a first input stage having an input configured to receive an input current, and an output;
a first transistor having a control terminal coupled to the output of the first input stage, and a current path;
a second transistor having a control terminal and a current path;
a current mirror coupled between the current path of the first transistor and the current path of the second transistor;
a first output stage having an input coupled to the control terminal of the second transistor, and an output configured to provide an output current;
a first resistor coupled between the output of the first input stage and the control terminal of the first transistor;
a first capacitor coupled to the first resistor and to the control terminal of the first transistor; and
a first feedback path having an output coupled to the first resistor, the first feedback path including:
a buffer having an output coupled to the control terminal of the first transistor, and
a second capacitor.

10. The circuit of claim 9, wherein an input of the first feedback path is coupled to the control terminal of the second transistor.

11. The circuit of claim 9, wherein an input of the first feedback path is coupled to a control terminal of a third transistor of the current mirror.

12. The circuit of claim 9, wherein the second capacitor is coupled between an input of the buffer and the current mirror.

13. The circuit of claim 9, wherein the second capacitor is coupled between the output of the buffer and the first resistor.

14. The circuit of claim 9, wherein the first input stage comprises:
a third transistor having a current path coupled between the input of the first input stage and a reference terminal, and a control terminal coupled to the control terminal of the first transistor; and
a fourth transistor having a first current path terminal coupled to a supply terminal, and a second current path terminal coupled to the input of the first input stage.

15. The circuit of claim 14, wherein the first current path terminal of the fourth transistor is coupled to the control terminal of the first transistor via the first resistor and via a second resistor.

16. The circuit of claim 9, wherein the first output stage comprises a third transistor having a current path coupled to the output of the first output stage, and a control terminal coupled to the current path of the second transistor.

17. The circuit of claim 9, further comprising a low-pass filter coupled between the current path of the second transistor and the input of the first output stage.

18. A transceiver comprising:
a first filter having an input and an output;
a first mixer having an input and an output, the input of the first mixer coupled to the output of the first filter;
a second mixer having an input and an output; and
a second filter having an input and an output, the input of the second filter coupled to the output of the second mixer, wherein the first filter includes:
a first amplifier having an input coupled to the input of the first filter and an output;
a second amplifier having an input coupled to the output of the first amplifier and an output; and
a first feedback path coupled between the second amplifier and the input of the first amplifier and including a buffer and a capacitor.

19. The transceiver of claim 18, further comprising:
a duplexer having a first terminal, and a second terminal, wherein the first terminal of the duplexer is coupled to the output of the first mixer, and wherein the input of the second mixer is coupled to the second terminal of the duplexer.

20. The transceiver of claim 18, wherein the second filter includes a third amplifier having an input and an output, a fourth amplifier having an input and an output, and a second feedback path from the output of the fourth amplifier to the input of the third amplifier and including a second buffer and a second capacitor in series, wherein the input of the third amplifier is coupled to the output of the second filter, and wherein the output of the third amplifier is coupled to the input of the second amplifier.
